(19) United States
(12) Patent Application Publication
(10) Pub. No.: US 2009/0114283 A1
(43) Pub. Date: May 7, 2009

(54) DYE-SENSITIZED SOLAR CELL

(75) Inventors: Rong-Ho LEE, Chia-Yi County (TW); Yu-Wei HUANG, Taoyuan County (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: National Yunlin University of Science and Technology

(21) Appl. No.: 12/019,286

(22) Filed: Jan. 24, 2008

(30) Foreign Application Priority Data
Nov. 2, 2007 (TW) 096141577

(51) Int. Cl. H01L 31/04

(52) U.S. Cl. 136/260; 136/263

(57) ABSTRACT

A dye-sensitized solar cell includes a first substrate, a first electrode layer, a photosensitive dye layer, an electrolyte layer, a second electrode layer, and a second substrate. The first electrode layer is disposed on the first substrate. The photosensitive dye layer is disposed on the first electrode layer. The electrolyte layer is disposed on the photosensitive dye layer, and the electrolyte layer is composed of an organic electrolyte material. The second electrode layer is disposed on the electrolyte layer, and the second substrate is disposed on the second electrode layer. A stable and effective oxidation and reduction reaction is performed between the elements by the characteristics of the composition and the structure of the electrolyte material, thus improving the photoelectric conversion efficiency and the stability of the dye-sensitized solar cell.

### CROSS-REFERENCE TO RELATED APPLICATIONS

This non-provisional application claims priority under 35 U.S.C. § 119(a) on Patent Application No(s). 096141577 filed in Taiwan, R.O.C. on Nov. 2, 2007 the entire contents of which are hereby incorporated by reference.

### BACKGROUND OF THE INVENTION

1. Field of Invention

The present invention relates to a dye-sensitized solar cell, and more particularly to an electrolyte material in a dye-sensitized solar cell and a structure thereof.

2. Related Art

Due to the problems of global climate change, air pollution, and resource shortage, the possibility of taking solar cells as one of the main sources for power supply has widely drawn more and more attentions. In recent years, the market of silicon-based solar cells has been rapidly developed. The principle of the silicon-based solar cells is based on the photovoltaic effect of the semiconductor. Although the silicon-based solar cells have relatively high photoelectric conversion efficiency, as the manufacturing process is complicated and the cost is high, it is limited to some special applications. Therefore, many main research institutes all over the world are dedicated to the research of technologies relevant to solar energy, and expect to develop new materials capable of reducing the product cost and meanwhile improving the photoelectric conversion efficiency.

In the late 20^{th} century, a dye-sensitized solar cell is developed, which has advantages such as low cost, light weight, being flexible, and easy to be manufactured with a large area. Accordingly, the dye-sensitized solar cell has gradually become a hot research issue in this field. In the dye-sensitized solar cell, a photosensitive dye is formed on a semiconductor electrode of a conductive substrate. When the photosensitive dye absorbs the sunlight, the electrons of a valence layer in the photosensitive dye is excited by the light, and the electrons are transited to an excited state, but the excited state is not stable, the electrons are soon transferred to a conductive layer of the semiconductor, and then transferred to the electrode via an external circuit. The dye carries with positive charge, and the dye losing electrons gets electrons from an electrolyte in the cell. The dye in oxidization state is reduced by the electrolyte, and the oxidized electrolyte receives electrons at the counter electrode and reduced to a ground state, thus completing the electron transfer process.

One reason that influences the photoelectric conversion efficiency of the dye-sensitized solar cell lies in a stable and effective oxidation and reduction reaction, which makes the electrons and holes stably exist between the films in the cell in balance. Accordingly, how to improve the composition and structure of the electrolyte material, so as to enhance the photoelectric conversion efficiency of the dye-sensitized solar cell, becomes one of the urgent problems to be solved by the researchers.

### SUMMARY OF THE INVENTION

In view of the above problems, the present invention is directed to provide a composition and a structure of an electrolyte material in a dye-sensitized solar cell, so as to perform a stable and effective oxidation and reduction reaction between the elements by the characteristics of the composition and the structure of the electrolyte material, thus improving the photoelectric conversion efficiency and the stability of the dye-sensitized solar cell.

The present invention provides a dye-sensitized solar cell, which includes a first substrate, a first electrode layer, a photosensitive dye layer, an electrolyte layer, a second electrode layer, and a second substrate. The first electrode layer is disposed on the first substrate. The photosensitive dye layer is disposed on the first electrode layer. The electrolyte layer is disposed on the photosensitive dye layer, and the electrolyte layer is composed of an organic electrolyte material. The second electrode layer is disposed on the electrolyte layer, and the second substrate is disposed on the second electrode layer.

In an embodiment of the present invention, the organic electrolyte material is composed of an organic conjugate conformation and a salt containing segment. The salt containing segment has the property of being capable of carrying negative charged ions. The organic conjugate conformation is selected from polyaniline, polypyrrole, polyfluorenes, polycarbazole, polythiophene, poly(fluorene-triphenylamine), and a group consisted thereby. The organic conjugate conformation is a small molecular conformation, an oligomer conformation, or a polymer material conformation. The molecular chain conformation of the organic conjugate conformation is selected from among main chain conformation, side chain conformation, star shape chain conformation, or branched chain conformation. The salt containing segment is selected from among quaternary ammonium salt containing segment, Viologen salt containing segment, N-methylpyridine salt containing segment, imidazole salt containing segment, pyrrolidone salt containing segment, and a group consisted thereby. The negative charged ions in the salt containing segment is selected from among halogen ions, ClO₄⁻, SO₃⁻, PF₆⁻, or CF₃SO₃⁻.

In an embodiment of the present invention, a transparent electrode and an electron transport layer are further included. The transparent electrode is disposed between the second electrode layer and the second substrate, and the material of the transparent electrode is indium-tin oxide. The electron transport layer is disposed between the first electrode layer and the photosensitive dye layer.

The composition and structure of the electrolyte material of the present invention has the organic conjugate conformation capable of transporting holes and a salt containing segment capable of carrying negative charged ions. The negative charged ions carried in the salt containing segment transport the electrons to the photosensitive dye molecules in oxidization state, and the organic conjugate conformation capable of transporting holes transports the holes to the second electrode, such that the oxidation and reduction reaction in the holes is performed stably and continuously. As the electrons and holes stably exist between the films in the cell in balance, the photoelectric conversion efficiency and the operation stability of the components in the dye-sensitized solar cell are effectively improved.

### BRIEF DESCRIPTION OF THE DRAWINGS

The present invention will become more fully understood from the detailed description given herein below for illustration only, and thus are not limitative of the present invention, and wherein:

FIG. 1 is a schematic cross-sectional view of a structure of a dye-sensitized solar cell according to an embodiment of the present invention; and

FIG. 2 is a schematic view of the variation of the photoelectric conversion efficiency of the dye-sensitized solar cell with different content of polymer electrolyte material blended according to an embodiment of the present invention with time.

### DETAILED DESCRIPTION OF THE INVENTION

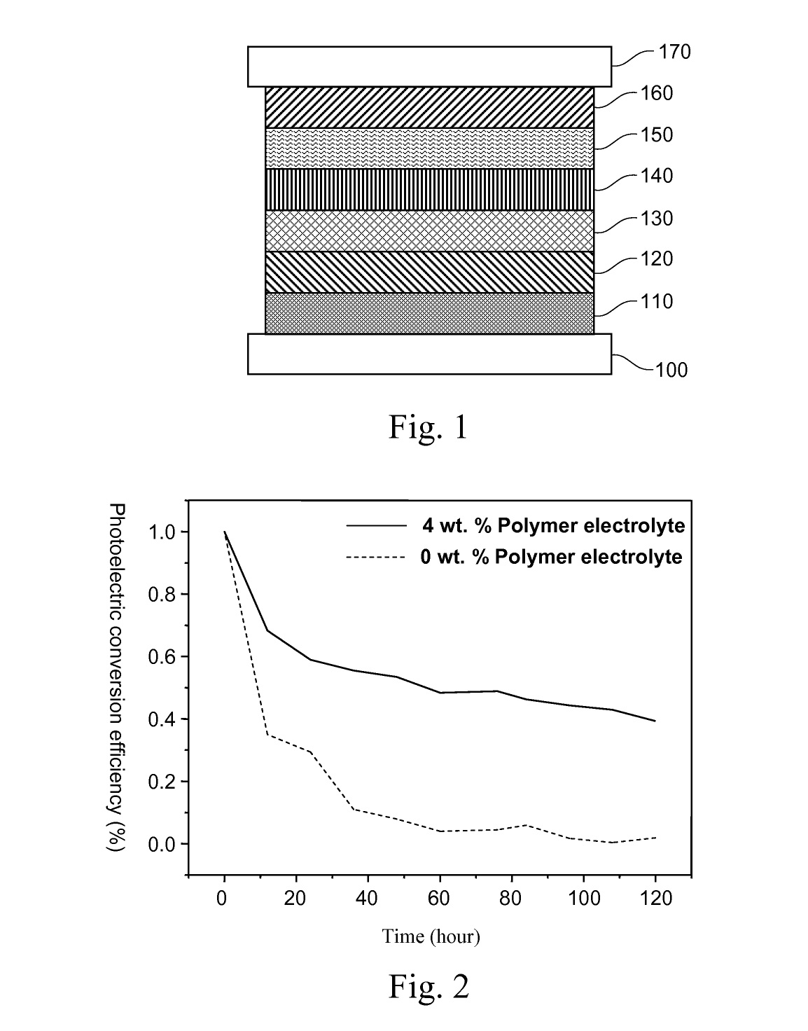

Referring to FIG. 1, a schematic cross-sectional view of a structure of a dye-sensitized solar cell according to an embodiment of the present invention is shown. As shown in FIG. 1, the dye-sensitized solar cell includes a first substrate 100, a first electrode layer 110, an electron transport layer 120, a photosensitive dye layer 130, an electrolyte layer 140, a second electrode layer 150, a transparent electrode layer 160, and a second substrate 170.

In an embodiment of the present invention, the electrolyte layer 140 is composed of an organic electrolyte material, and the organic electrolyte material is composed of an organic conjugate conformation and a salt containing segment. The salt containing segment has the property of being capable of carrying negative charged ions. The material of the organic conjugate conformation includes, but not limited to, polyaniline, polypyrrole, polyfluorene, polycarbazole, polythiophene, poly(fluorene-triphenylamine) and the group consisted thereby. The molecular chain conformation of the organic conjugate conformation is formed by the pattern polymerization of main chain conformation, side chain conformation, star shape chain conformation, or branched chain conformation. The repeated unit of the conjugate segment includes, but not limited to a small molecular conformation unit pattern, an oligomer conformation unit pattern, or a polymer material conformation unit pattern. The salt containing segment includes, but not limited to, quaternary ammonium salt containing segment, Viologen salt containing segment, N-methylpyridine salt containing segment, imidazole salt containing segment, pyrrolidone salt containing segment, and a group consisted thereby. The negative charged ions in the salt containing segment include, but not limited to, halogen ions, ClO₄⁻, SO₃⁻, PF₆⁻, or CF₃SO₃⁻.

In this embodiment, the electrolyte layer 140 is disposed on the photosensitive dye layer 130. The electrolyte can be a liquid electrolyte, a semi-solid electrolyte, or a solid electrolyte.

In an embodiment of the present invention, the material of the first electrode layer 110 can be fluorine-doped tin oxide (SnO₂:F, FTO). The electron transport layer 120 is disposed between the first electrode layer 110 and the photosensitive dye layer 130, and the material of the electron transport layer 120 can be a metal oxide, such as titanium dioxide, zinc oxide, cadmium oxide, tin dioxide, or a composite metal oxide, such as zinc-titanium oxide, vanadium-titanium oxide. The transparent electrode layer 160 is disposed between the second electrode layer 150 and the second substrate 170, and the material of the transparent electrode layer 160 can be indium-tin oxide (ITO). The material of the second electrode layer 150 can be gold, platinum, and an alloy thereof, graphite, or a carbide material.

In an embodiment of the present invention, the material of the photosensitive dye layer 130 can be organometallic complexes containing ruthenium, including N3 dye, N712 dye, and N719 dye, or a black dye. The chemical formulae of N3 dye, N712 dye, N719 dye, and the black dye are [cis-di(thiocyanato)-bis(2,2′-bipyridyl-4,4′-dicarboxylic acid)-ruthenium(II)], [cis-di(thiocyanato)-bis(2,2′-bipyridyl-4-carboxylate-4′-carboxylic acid)-ruthenium(II)], (Bu₄N)₄[Ru(dcbpy)₂(NCS)₂] (Bu₄N=tetrabutyl-ammonium and dcbpyH₂=2,2′-bipyridyl-4,4′-dicarboxylic acid), and [(tri(cyanato)-2,2′,2″-terpy-ridyl-4,4′,4″-tri-carboxylate) Ru(II)] respectively.

The first substrate 100 and the second substrate 170 can be transparent glass or transparent plastic, respectively. The material of the transparent plastic can be poly-ethyleneterephthalate, polyester, polycarbonates, polyacrylates, or polystyrene.

Referring to FIG. 1 again, in a preferred embodiment of the present invention, the method for preparing a dye-sensitized solar cell includes the following steps. First, by using a transparent conductive glass as a first electrode layer 110, a layer of titanium dioxide is covered on the first electrode layer 110 through screen printing or coating, so as to serve as an electron transport layer 120. Next, the electron transport layer 120 is immersed in a solution of N719 dye, which serves as a photosensitive dye layer 130, and a step of heating and drying is performed, such that N719 dye is adsorbed on the surface of the electron transport layer 120. Thereafter, an electrolyte layer 140 is formed, and a second electrode layer 150 composed by gold, platinum (Pt), and an alloy thereof, graphite, or a carbide material is formed by catalyst heating of spin coating, vacuum evaporation, or sputtering.

In this embodiment, a new electrolyte formulation is formed by blending a polymer electrolyte material Poly[9,9-bis(3′((N,N-methyl)-N-ethylammonium)-propyl)-2,7-fluorene]]Diiodide of the present invention into a 3-methoxypropionitrile liquid electrolyte solution containing 1,2-dimethyl-3-propylimidazolium iodide (DMPII), LiI, I₂, and 4-tetra-butyl pyridine (TBP) in proportion. In a dye-sensitized solar cell fabricated by using an electrolyte formulation with different contents of the polymer electrolyte materials blended, as the composition of electrolyte material is capable of transporting holes and electrons, the oxidation and reduction reaction in the cell is performed stably and continuously.

It can be known with reference to the experimental data in Table 1 that high photoelectric conversion efficiency can be obtained by blending 6 wt % of Polymer electrolyte material in the liquid electrolyte and using N719 dye as the photosensitive dye layer of the dye-sensitized solar cell. The open-circuit voltage Voc of the element is measured to be 0.75 V, the short-circuit current (Jsc) is measured to be 34.70 mA/cm², the fill factor (FF) is measured to be 0.40, and the photoelectric conversion efficiency is improved to 10.29%. The dye-sensitized solar cell fabricated by the electrolyte of the new formulation can effectively improve the photovoltaic effect and the photocurrent efficiency of the dye-sensitized solar cell.

TABLE 1
Properties of dye-sensitized solar cell with different contents of the
electrolyte materials blended

| | Polymer | | | | |
|---|---|---|---|---|---|
| | electrolyte | | | | |
| Solar Cells | Content | Voc (V) | Jsc (mA/cm²) | FF | η (%) |
| Cell 1 | 1 wt % | 0.60 | 31.15 | 0.40 | 7.39 |
| Cell 2 | 4 wt % | 0.65 | 34.64 | 0.39 | 8.66 |
| Cell 3 | 6 wt % | 0.75 | 34.70 | 0.40 | 10.29 |
| Cell 4 | 10 wt % | 0.70 | 37.50 | 0.39 | 10.14 |

Referring to FIG. 2, a schematic view of the variation of the photoelectric conversion efficiency of the dye-sensitized solar cell with different contents of polymer electrolyte material blended according to an embodiment of the present invention with time. Axis X and Axis Y in FIG. 2 represent time and photoelectric conversion efficiency respectively, the dash line represents dye-sensitized solar cell without polymer electrolyte material blended in the electrolyte, and the solid line represents the dye-sensitized solar cell with 4 wt % of polymer electrolyte material blended in the electrolyte. It can be known from FIG. 2 that the photoelectric conversion efficiency of the dye-sensitized solar cell with polymer electrolyte material blended in the electrolyte reducing with time is significantly lower than that of the dye-sensitized solar cell without polymer electrolyte material blended in the electrolyte, and thus it is known that the solar cell with polymer electrolyte material blended can significantly improve the stability of the cell. The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A dye-sensitized solar cell, comprising:
a first substrate;
a first electrode layer, disposed on the first substrate;
an electron transport layer, disposed on the first electrode layer;
a photosensitive dye layer, disposed on the first electrode layer;
an electrolyte layer, disposed on the photosensitive dye layer, a material of the electrolyte layer being an organic electrolyte material;
a second electrode layer, disposed on the electrolyte layer;
a transparent electrode layer, disposed on the second electrode layer; and
a second substrate, disposed on the second electrode layer.

2. The dye-sensitized solar cell as claimed in claim 1, wherein the organic electrolyte material is an organic conjugate conformation and a salt containing segment, and the salt containing segment has a property of carrying negative charged ions.

3. The dye-sensitized solar cell as claimed in claim 2, wherein the organic conjugate conformation is selected from a group of polyaniline, polypyrrole, polyfluorenes, polycarbazole, polythiophene, and poly(fluorene-triphenylamine).

4. The dye-sensitized solar cell as claimed in claim 2, wherein the organic conjugate conformation is selected from a group of small molecular conformation, oligomer conformation, or polymer material conformation.

5. The dye-sensitized solar cell as claimed in claim 2, wherein the molecular chain conformation of the organic conjugate conformation is selected from a group of main chain conformation, side chain conformation, star shape chain conformation, or branched chain conformation.

6. The dye-sensitized solar cell as claimed in claim 2, wherein the salt containing segment is selected from among quaternary ammonium salt containing segment, Viologen salt containing segment, N-methylpyridine salt containing segment, imidazole salt containing segment, and pyrrolidone salt containing segment.

7. The dye-sensitized solar cell as claimed in claim 2, wherein the negative charged ions in the salt containing segment is selected from a group of halogen ions, ClO₄⁻, SO₃⁻, PF₆⁻, or CF₃SO₃⁻.

8. The dye-sensitized solar cell as claimed in claim 1, wherein material of the first electrode layer is fluorine-doped tin oxide (FTO).

9. The dye-sensitized solar cell as claimed in claim 1, further comprising an electron transport layer disposed between the first electrode layer and the photosensitive dye layer.

10. The dye-sensitized solar cell as claimed in claim 9, wherein a material of the electron transport layer is selected from a group of metal oxides comprising titanium dioxide, zinc oxide, cadmium oxide, and tin dioxide, or composite metal oxides comprising zinc-titanium oxide and vanadium-titanium oxide.

11. The dye-sensitized solar cell as claimed in claim 1, wherein a material of the photosensitive dye layer is selected from a group of organometallic complexes containing ruthenium.

12. The dye-sensitized solar cell as claimed in claim 11, wherein the organometallic complexes containing ruthenium comprises N3 dye, N712 dye, N719 dye, black dyes, and organic dye molecules.

13. The dye-sensitized solar cell as claimed in claim 1, wherein a material of the second electrode layer is selected from a group of gold, platinum, an alloy of gold and platinum, graphite, and a carbide material.

14. The dye-sensitized solar cell as claimed in claim 1, wherein a material of the transparent electrode layer is indium-tin oxide.
